(19) United States
(12) Patent Application Publication
(10) Pub. No.: US 2007/0298168 A1
(43) Pub. Date: Dec. 27, 2007

(54) Multifunctional carbon nanotube based brushes

(75) Inventors: Pulickel M. Ajayan, Clifton Park, NY (US); Anyuan Cao, Honolulu, HI (US); Vinod Veedu, Honolulu, HI (US); Mohammad Naghi Ghasemi-Nejhad, Honolulu, HI (US); Xuesong Li, Troy, NY (US)

Correspondence Address: FOLEY AND LARDNER LLP;SUITE 500, 3000 K STREET NW, WASHINGTON, DC, 20007, US

(73) Assignee: RENSSELAER POLYTECHNIC INSTITUTE

(21) Appl. No.: 11/449,863

(22) Filed: Jun. 9, 2006

(51) Int. Cl. B05D 5/00; C23C 16/00; B05D 1/32

(52) U.S. Cl. 427/249.1; 427/282

(57) ABSTRACT

A brush includes a microscale handle and nanostructure bristles, such as carbon nanotube bristles, located on at least one portion of the handle.

### STATEMENT REGARDING FEDERALLY SPONSORED RESEARCH OR DEVELOPMENT

This invention was made with U.S. government support under National Science Foundation Grant No. 0117792 and under Office of Naval Research Grant No N00014-00-1-0692. The United States government may have rights in this invention.

### FIELD OF THE INVENTION

The present invention relates generally to brushes and specifically to microscale brushes comprising nanotube or other nanostructure bristles.

### BACKGROUND

Brushes are common tools for use in industry and our daily life, performing a variety of tasks such as cleaning, scraping, applying and electrical contacting. Typical materials for constructing brush bristles include animal hairs, synthetic polymer fibers and metal wires. The performance of these bristles has been limited by the oxidation and degradation of metal wires, poor strength of natural hairs, and low thermal stability of synthetic fibers.

### SUMMARY

One embodiment of the invention provides a brush comprising a microscale handle and nanostructure bristles located on at least one portion of the handle.

### BRIEF DESCRIPTION OF THE DRAWINGS

FIG. 1a is a schematic illustration of a method partial masking of SiC fibers in order to grow nanotubes only on the fiber top.

FIGS. 1b-g are SEM images of micro brushes as follows. FIG. 1b is an image of as-grown nanotubes on top of SiC fibers, forming three prongs symmetrically distributed around each fiber. FIG. 1c is an image of a single brush (resembling a dust sweeper) consisting of nanotube bristles and a fiber handle. The bristles have a height (nanotube length) of 60 μm, and span of over 300 μm along the handle. FIG. 1d is an image of a smaller brush, with a bristle height of only 10 μm and span of 30 μm. FIG. 1e is an image of a two-prong brush resembling a hand-held fan. FIG. 1f is an image of a one-prong toothbrush shaped brush. FIG. 1g is an image of a double-ended brush with different bristles on each end. Scale bars in FIGS. 1c, e, f and g are 50 μm. FIG. 1h is an image of a brush with regular nanotube bristles (250 microns wide, 60 microns in height) separated by 500 microns along the handle. The brush is made by patterning a gold mask layer on SiC fibers.

FIG. 1i is a plot of shear-stress versus strain during tensile testing of brushes for measuring the adhesion strength of nanotube bristles, for both as-grown and annealed brushes. The inset is an illustration of the setup for pulling nanotubes away from the handle.

FIG. 2 illustrates multiple functions performed by nanotube brushes. FIG. 2a is a schematic illustration of a ‘sweep’ and ‘rotate’ brush that can be used to clean nanoparticles from flat surfaces and narrow trenches, paint the inside of capillaries, and adsorb liquid chemicals trapped in small area. FIG. 2b is a micrograph of a dump of nanoparticles formed by a sweep brush. FIG. 2c is a SEM image of 10-μm-wide trenches cleaned by sweeping the brush over the surface. The inset shows dispersed nanoparticles inside trenches before brushing. FIG. 2d is a photograph of a “rotate” brush attached to an electrical motor. FIG. 2e is an SEM image showing use of a “rotate” brush first to clean the inside of a contaminated capillary (inner diameter of 300 μm), and then paint the inner wall red.

FIG. 3 illustrates selective adsorption of chemicals from solution by nanotube brushes. FIG. 3a is a plot of absorption versus wavelength which shows the ultraviolet-visible spectrum of ZnPP solution (in DMF) before and after rotate-brushing. The peak at 420 nm is the Soret band of ZnPP. The inset shows characterized ZnPP concentration versus Soret band intensity. The instrument used was an ultraviolet-visible spectrometer (Perkin Elmer, Lambda 2). FIG. 3b is a plot of absorption versus wavelength which shows the selective adsorption of ZnPP from a mixture of ZnPP (1.35 mg l⁻¹) and ZnTPP (0.5 mg l⁻¹) after brushing the solution for different times (2 min and 5 min). The emergence of a shoulder (403 nm) near the Soret band (424 nm) indicates more ZnTPP left in the solution whereas ZnPP has been selectively adsorbed. The inset shows ultraviolet-visible absorption spectrum of pure ZnTPP with a characteristic peak at 403 nm (see arrow). FIG. 3c is a schematic illustration showing the dipping of a pyrene-functionalized nanotube brush to pick up silver ions in solution. FIG. 3d is a schematic illustration of the functionalization of the brush, adsorption of silver ions and hydrogen reduction for SEM examination. FIG. 3e shows the XPS spectrum of Ag adsorption by as-grown (dark line) and pyrene-functionalized (light line) brushes. The inset shows Ag 3d peaks from pyrene functionalized brushes. FIG. 3f is an SEM image of Ag particles (after hydrogen reduction) adsorbed on the surface of the nanotube brushes.

FIG. 4 illustrates electrical characterization of nanotube brushes and the construction of a flexible electromechanical switch. FIG. 4a is a four probe current-voltage measurement of a single brush (1-mm bristle span with 1-mm handle), showing an electrical resistance of <15 kΩ. FIG. 4b is a current-voltage plot of nanotube bristles only, with a resistance of <2 kΩ. FIG. 4c is a plot of current versus voltage for brushes being subjected to a pressing stress and no pressing stress to demonstrate the pressure dependence of resistance of the brushes. FIG. 4d is a plot of brush resistance versus temperature to demonstrate the temperature dependence of resistance of the brush. FIG. 4e is a schematic illustration of a design of an electrical switch device based on a motor-driven brush with the nanotube bristles as the touch-contact structure. An ohm meter was connected to the nanotubes and the underlying metal sheet to record the device resistance. FIG. 4f is a plot of resistance versus time illustrating a periodic resistance change while the brush was rotating at a constant speed (˜7 r.p.m.), with an exchange of the ‘on’ (˜50 kΩ) and ‘off’ (infinite) status of the device.

FIG. 5a is a schematic illustration of an apparatus for growing nanotube bristles. FIGS. 5b, 5c and 5d are SEM images of the nanotube bristles.

### DETAILED DESCRIPTION

An embodiment of the invention provides a brush comprising a microscale handle and nanostructure bristles located on at least one portion of the handle. The nanostructure bristles may comprise any bristle shaped or elongated shaped nanostructure having a nanoscale width or diameter, such as a diameter less than 500 nm, for example a diameter between 1 nm and 100 mm. While carbon nanotubes, such as multi-walled carbon nanotubes, are the preferred bristle material, other nanostructure materials, such as single-walled nanotubes, non-carbon nanotubes (boron nitride, etc. nanotubes), nanohorns, nanobelts or nanowires (such as metal, semiconductor or insulating nanowires, such as for example, nickel, silicon or nickel oxide nanowires) may be used as a bristle material.

The microscale handle may comprise any suitable material which can support the nanostructure bristles. For example, the handle may comprise metal, semiconductor, ceramic, polymer, glass, glass-ceramic, quartz, etc. In one example, the handle comprises a silicon carbide fiber. However, any other suitable material may also be used. The handle is preferably rod shaped and has a circular cross section (i.e., a cylindrical handle) or a rectangular or irregular cross section (i.e., an elongated rectangular or other shaped handle). Preferably the handle has a width (for a non-cylindrical handle) or diameter (for a cylindrical handle) that is less than 1000 microns, such as 10 to 100 microns for example. For example, the handle may comprise a microfiber having a diameter of 50 microns or less, and a length of 1000 microns to 10 cm, such as 1 to 10 mm for example.

The bristles extend in at least one direction, and in some embodiments in a plurality of directions from at least one portion of the handle. For example, the bristles may extend radially in 360 degrees from a cylindrical rod shaped handle. The bristles may be located only on one end of the rod shaped handle, on both ends of the handle, in the middle of the handle and/or be located along plural portions along the length of the handle.

The brush may be operated manually or mechanically. For example, the handle may be connected to a motor which moves the handle in at least one of a sweeping or rotating motions. The brush may also be used as an electrical contact or switch located in an electronic device.

Carbon nanotubes, having a typical one-dimensional nanostructure, have excellent mechanical properties, such as high modulus and strength, high elasticity and resilience, thermal conductivity and large surface area (50-200 m²g⁻¹). The present inventors developed multifunctional, conductive brushes with carbon nanotube bristles grafted on fiber handles. The micro brushes can be used for tasks such as cleaning of nanoparticles from narrow spaces, coating of the inside of holes, selective chemical adsorption, and as movable electromechanical brush contacts and switches. The nanotube bristles can also be chemically functionalized for selective removal of heavy metal ions and other species from fluids.

In general, the brush may be used for brushing an object. In one embodiment, brushing the object comprises brushing debris from a surface, such as brushing nanoparticles from a surface of a semiconductor device. In another embodiment, brushing the object comprises mechanically moving the brush such that the bristles contact a solid surface or a liquid. In another embodiment, brushing the object comprises coating a surface of the object with paint or another coating composition or material located on the bristles. In another embodiment, brushing the object comprises stirring a liquid by moving the brush in the liquid. In another embodiment, brushing the object comprises providing the brush into a fluid, such as a gas or liquid, to selectively absorb at least one component of the fluid onto the bristles. The bristles may be functionalized to selectively absorb the at least one component of the fluid. In another embodiment, brushing the object comprises moving the bristles to contact a conductive surface to form an electrical contact between the conductive surface and the handle.

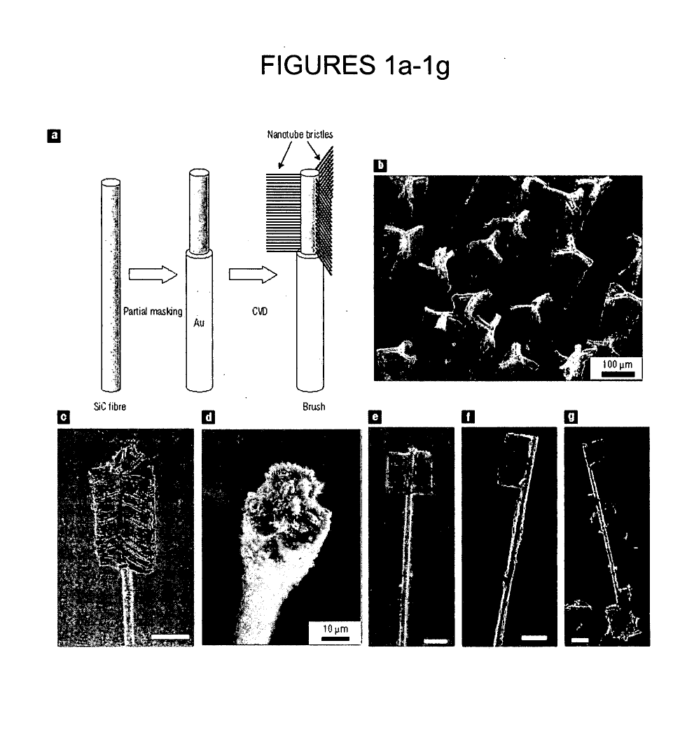

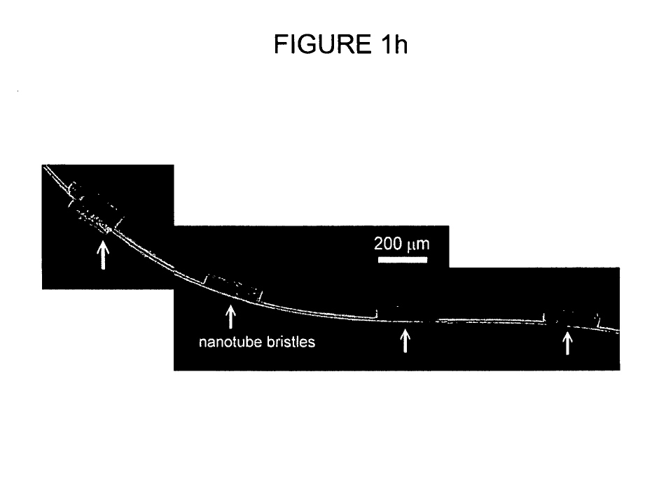

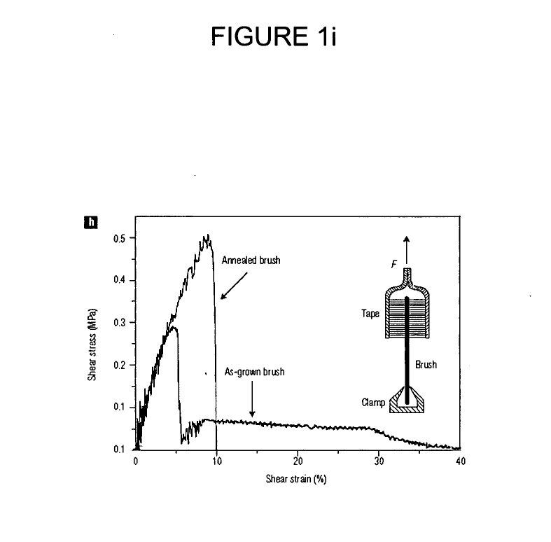

In one non-limiting example, the nanotube brush consists of a silicon carbide fiber (SiC, diameter 16 μm) as the handle and aligned multiwalled carbon nanotubes grafted on the fiber ends as bristles. The nanotubes (average diameter 30 nm) were grown by selective chemical vapor deposition (CVD) with ferrocene and xylene as the precursors. Before CVD, individual SiC fibers were partially masked by a 15-nm Au layer except for the top ends as shown in FIG. 1a and placed vertically in the furnace to selectively grow the nanotube bristles on the exposed portion of the fiber, as shown on the right side of FIG. 1a. The Au layer serves as a physical mask to limit the growth of the nanotubes to the unmasked fiber ends. FIG. 1b shows the scanning electron microscope (SEM, JEOL JSM-6330-F) image of the top morphology of as-grown nanotubes on fibers. Here, the nanotubes grew in three prongs symmetrically distributed around the center fiber, and have a uniform length (about 60 μm after 40 minutes growth) along the fiber axis. Within the prongs, nanotubes are well aligned with tips exposed at the edges.

FIG. 1c shows an individual brush with 60-μm-long nanotube bristles spanning over 300 μm. Compared with current commercial brushes having bristles of about 0.038 to about 1.9 mm in diameter and a core block size of more than 3 mm, these nanotube brushes have bristle sizes 1,000 times smaller and the overall brush size is decreased more than 20 times. The total weight of a single brush (plus a 1-cm-long fiber handle) is less than 50 μg. Nonetheless, the brush as shown in FIG. 1c contains nearly 1.7×10⁶ bristles (nanotubes), with an area density of greater than 1×10⁸ mm⁻², such as about 1.2×10⁸ mm⁻² (calculation based on the measurements of sample weight), which is about five orders higher than available commercial brushes having an area density of 10³ mm⁻². When these nanotube bristles are placed on a plain surface (assuming that all the nanotubes have the same height), the contact area (where the nanotube tips touch the surface) is at least 1×10³ μm², such as 27×10³ μm², which is greater than 8%, such as about 8.8% of the total bristle front surface (14.4×10³ μm²), slightly higher than a conventional toothbrush having a contact area of 7.9% (based on a head size of 1×2 cm² and 500 bristles 0.2 mm in diameter, 1 cm in height). The actual contact area could be larger if the bristles are pressed against the contacting surface and nanotubes are bent (as larger portions of the nanotubes would engage the surface). In addition, once immersed in a solution, the total liquid-nanotube contact area is greater than 9×10⁶ μm², such as 9.8×10⁶ μm² over a bristle volume of 8.64×10⁵ μm³. The contact surface area per volume is greater than 11 μm² μm-³, such as about 11.3 μm² μm⁻³, three orders higher than a typical toothbrush (1.57×10⁻² μm²/μm⁻³).

The nanotube brush contact area is calculated as follows. The weight of a sample of 1×1 cm² size and 100 μm height was measured to be 1.7 mg. The weight of a single multi-walled nanotube (outer and inner diameter of 30 and 10 nm, respectively, based on transmission electron microscopy examination, length 100 μm) is calculated to be 1.4×10⁻¹³ g. Thus the number of nanotubes per unit area is 1.2×10⁸ mm⁻². A three-prong brush as seen in FIG. 1c with 60-μm bristle height and 300-μm span has 1.7×10⁶ bristles. This number was used to derive the contact area when the brush was placed on a surface or immersed in a solution, assuming all the nanotubes have the same height (length). The surface contact area equals the bristle number multiplied by nanotube tip size, and the liquid contact area equals the bristle number multiplied by individual nanotube surface area.

Various styles of brushes were obtained by varying the Au mask area and pattern on SiC fibers and growth conditions. The brush size, including trim length (nanotube length) and bristle span (the length of handle covered by bristles), were well controlled during the CVD process. The trim length can be varied from hundreds down to a few micrometers depending on the growth time. By adjusting the Au-masked portion of the SiC fiber, brushes were obtained with bristle spans ranging from several micrometers, such as at least 20 micrometers, to several millimeters such as 3 mm. For example, FIG. 1d shows a brush with 30-μm span and 10-μm trim length formed from nanotubes grown for a short time (about 5 minutes). The geometry of the bristles can also be made different, such as three prongs shaped like a dust-sweeper (FIG. 1c), two prongs resembling a hand-held fan (FIG. 1e), and a one-prong “toothbrush” (FIG. 1f). Also, FIG. 1g shows a double-ended brush (with different bristle geometries and spans on each end) prepared by forming a gold mask on the middle portion of the fiber. Brushes having multiple bristles, regularly distributed along the handle, were fabricated by patterning gold mask along the fiber as shown in FIG. 1h. While SiC fibers were used in the example, fibers of any other materials may be used.

As the nanotubes are rooted on the surface of SiC fibers by direct growth, the adhesion between nanotubes and the fiber is characterized for evaluating the brush lifetime. A tensile test was performed to measure this adhesion by mechanically pulling away nanotubes from the handle. Adhesion measurements between nanotube bristles and the fiber handle were done in an Instron 5803 electromechanical tester. The brush handle was fixed by a clamp, and two pieces of gloss-finish multitask tapes (Scotch) were wrapped around the nanotube bristles. During the testing, the Scotch tape grabbed the nanotube bristles and moved away at a constant speed of 1 mm min⁻¹ until the whole bristle detached from the handle. Three-prong brushes with bristle spans of 1 to 2 mm were used for testing. Two stages were observed during the bristle detachment from the brush handle. First, the maximum shear stress was applied in order to strip nanotube ends off the SiC fiber. The shear strain (5.5%) includes the stretch and tilt of the nanotubes under stress. Second, the whole nanotube bristle moved away along the fiber until complete separation. The shear strain after maximum stress hereby represents the relative displacement between the bristles and the fiber. The remaining stress in this stage (˜0.05 MPa at 10%-30% displacement) indicates a small dynamic friction force during nanotube slipping. Here, the nanotubes experienced a shear stress at the nanotube-SiC interface, which eventually strips their ends away from the SiC fiber. The stress-strain curve of an as-grown brush (FIG. 1i) shows a maximum stress of 0.28 MPa before the bristles detached from the handle (for ten brushes tested, this stress ranged over 0.1-0.3 MPa). The adhesion strength can be improved by a subsequent annealing at 950° C. for several hours in argon (the failure stress nearly doubles, as shown by the curve in FIG. 1i). Here the annealing strengthens the interaction between carbon and the underlying silicon (SiC bonding), thereby substantially enhancing the bristle-handle adhesion. Annealing in other inert ambients at other temperatures, such as at temperatures over 900 C for at least two hours, such as 2-10 hours, may also be performed. Contact-brush operations (described below) were conducted to evaluate the brush lifetimes. For example, the rotating brush, contacting a metal surface in every rotation, after over 0.1 million cycles remains robust without shedding the nanotube bristles. It is believed that the flexibility of nanotubes can relieve the contact stresses as the brush touches a solid surface on each cycle.

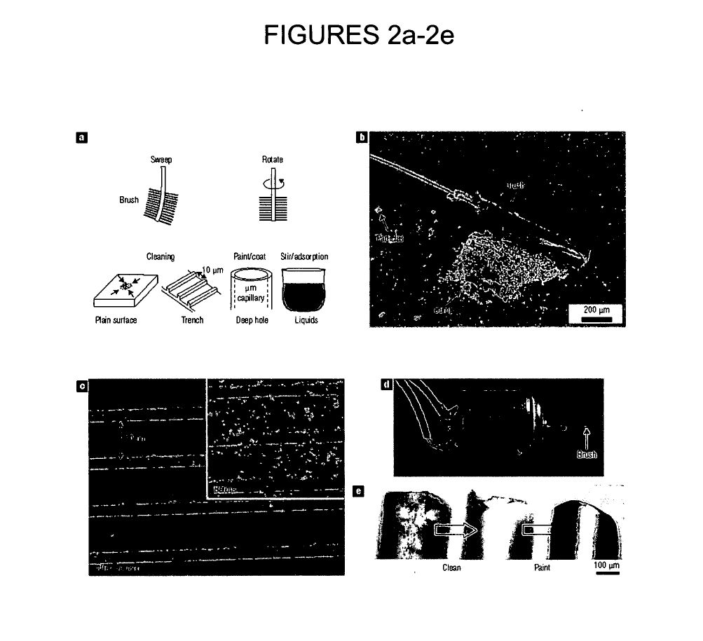

The nanotube brushes integrate a number of useful functions, such as but not limited to cleaning, painting, adsorption, electrical contact and switching, which are described here. Two basic brushing actions, “sweep” and “rotate”, were easily performed for different functions, as illustrated in FIG. 2a. Sweeping the brush is used for “dry” cleaning surfaces, for example, removing debris (left behind by processes, such as chemical mechanical polishing) or nanoparticles. The nanoparticles (commercial Fe₂O₃, average diameter<50 nm) were first dispersed on a plain silicon wafer, and then these particles (and aggregates) were swept into a dump pile with the brush as shown in FIG. 2b. The sweeping action was done manually by attaching the fiber to a 5-cm-long quartz rod as an extension handle, and the brush was directed to the nanoparticles under observation with an optical microscope. Although the nanoparticles were moved by the brushes, they didn't stick to the bristles and could be recollected. The same action using a commercial brush (for example, Anchor Set hand-held brush, bristle diameter 0.1 mm, from Gordon Brush), left most of the particles untouched. The nanotube brushes were used to clean rough surfaces, for example, narrow trenches (10 μm wide and 100 nm deep, as shown in FIG. 2c). This was done by sweeping along the trench direction three or four times, which removed nearly all of the nanoparticles sitting on top of the pattern as well as at the bottom of trenches, indicating that the flexible nanotube bristles can adapt to the geometry of narrow spaces. Sweeping bare SiC fibers only removed some of nanoparticles on the pattern top, but did not accomplish cleaning inside trenches. It should be noted that depressions having a shape other than a trench shape may also be brushed.

An electrically driven brush was formed by fixing it on the rotating head of a motor as shown in FIG. 2d, for the purpose of working inside deep holes and capillaries as illustrated in FIG. 2a. For example, a three-prong brush was rotated to sequentially clean and paint the inner wall of a capillary (diameter 300 μm, with pre-dispersed Fe₂O₃ nanoparticles), at 2,000 r.p.m. for 5 seconds. Then the brush was dipped into red paint (gloss enamel from Testors) and then rotated in the capillary again for 5 seconds, resulting in a uniform red coating on the inner wall of the capillary, as shown in FIG. 2e. Brush-coating has wide applications in thin-film coating and device decoration, and here the brushes may be used as disposables. Mechanically actuated brushes may also be used for sweeping, such as for sweeping the surface of the semiconductor devices.

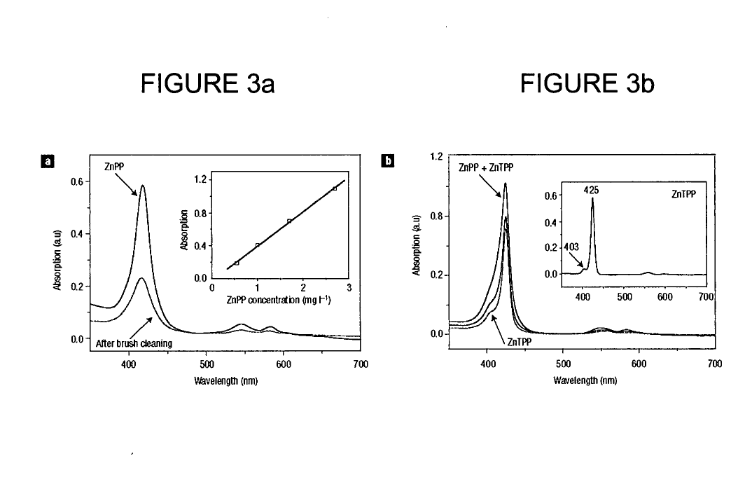

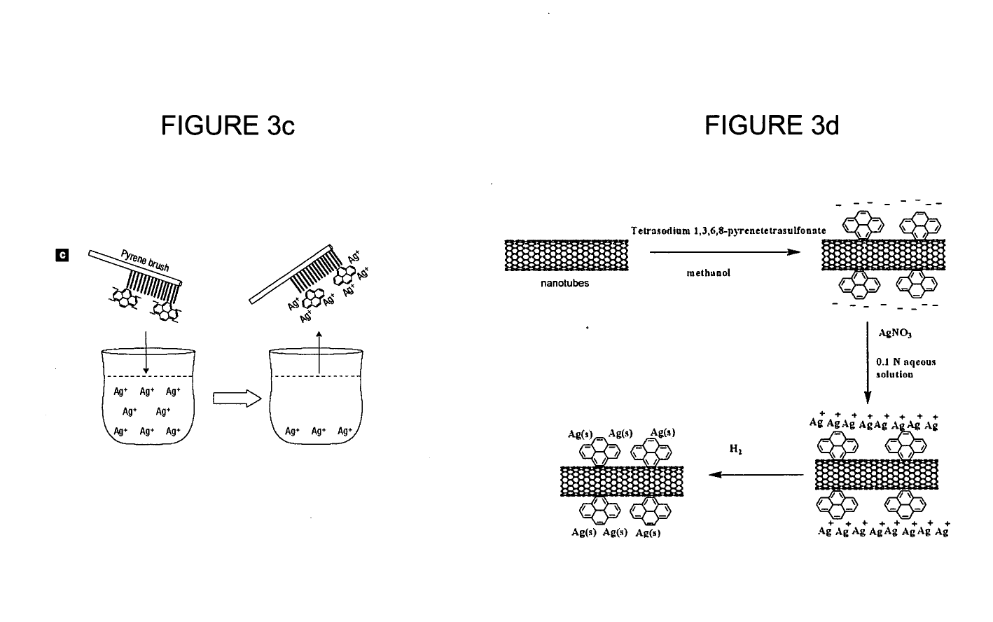

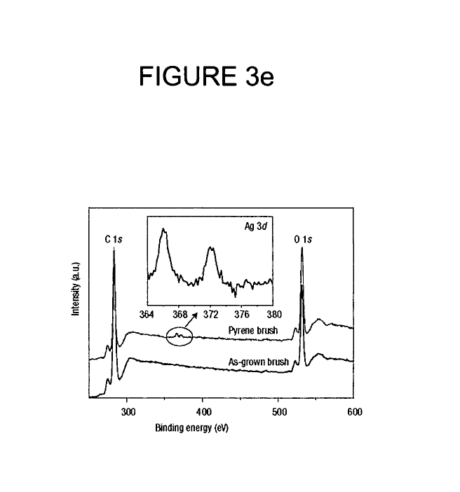

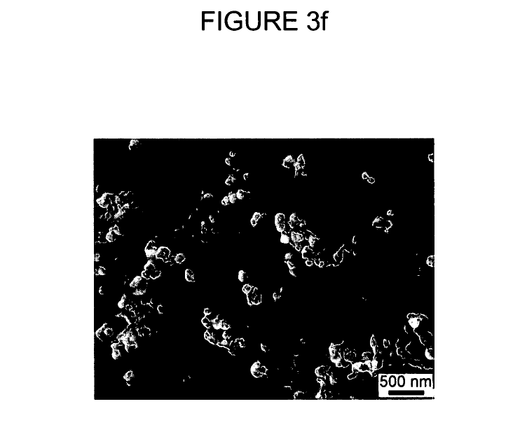

A rotating brush is suitable for working in liquid. For example, it can be used for selective adsorption and removal of organic chemicals such as, for example, porphyrins, which are functional dyes for developing photosynthetic materials. In porphyrins, zinc protoporphyrin IX (ZnPP) has a planar molecule, and can adsorb strongly on nanotube surfaces through π-π stacking interactions, whereas zinc tetraphenylporphyrin (ZnTPP) is nonplanar, only weakly interacting with nanotubes. A nanotube brush was immersed into a solution of ZnPP dissolved in dimethylformamide (DMF) housed in a capillary and stirred for 4 min. at 2,000 r.p.m. FIG. 3a shows the ultraviolet-visible absorption spectrum of the solution before and after brush stirring. The ZnPP concentration dropped from 1.5 to 0.6 mg/l, as indicated by the intensity change of the Soret band at 420 nm. Here the porous nanotube bristles act as a ‘molecule sponge’, and suck ZnPP molecules into the channels between nanotubes. Selective adsorption was done by brushing a mixed solution of ZnPP and ZnTPP in DMF for 5 min as shown in FIG. 3b. Although the intensity of the Soret band (at 425 nm) gradually decreased from 1.1 to 0.7, a shoulder at 403 nm clearly emerged, which is a characteristic peak of ZnTPP, indicating that ZnPP has been selectively removed (the concentration of ZnTPP remained unchanged, whereas the relative concentration ratio of ZnPP/ZnTPP decreased from 2.7:1 to 1.1:1). After rotation in solution, the brushes retained their structure and no nanotubes shed and contaminated the solution. However, several split sites along the bristles were observed. Collapse of the nanotubes on the brushes of the embodiments of the invention after dipping the brush in solution and taking it out was not observed. The inventors note that continuous nanotube films that are made hydrophilic by treatments, such as low temperature plasma oxidation, and which are formed on planar and weakly interacting substrates (such as mica or silica) have been observe to collapse.

The nanotube brushes were also functionalized to remove dissolved species, such as heavy metal ions (for example, Ag⁺) in solution (for example, silver nitrate, lethal in concentrations of 0.076 g/ml). Ionic pyrene derivative (1,3,6,8-pyrenetetrasulfonica acid tetrasodium) with three SO⁻₃ per molecule was grafted onto nanotube brushes to pick up Ag⁺ by the attraction between SO⁻₃ and Ag⁺ through a simple ‘dip’ action as shown in FIG. 3c. Functionalization of nanotube brushes with 1,3,6,8-pyrenetetrasulphonic acid tetrasodium salt was carried out by firstly dissolving 200 mg pyrene into 50 ml methanol, and immersing the brushes in the solution for 24 hours at room temperature (with slight stirring to avoid destroying the brush structure). The pyrene-grafted brushes were isolated by filtering the solution through a 200-nm Teflon membrane with complete washing by methanol to get rid of the free pyrene residues, and dried under vacuum at 50° C. for 12 hours. After Ag⁺ adsorption, the brushes were placed in a bottle filled with 15% H₂ in Ar for 24 hours to reduce the silver ions into solid particles, as schematically illustrated in FIG. 3d. The brushes were soaked into 20 ml silver nitrate (AgNO₃, 0.1 N) for 10 minutes, which was kept stirred, and then rinsed in distilled water to remove the residue solution on the brush surface. As-grown brushes without any functionalization were tested for reference. The adsorption of silver on brushes was characterized by X-ray photoelectron spectroscopy (XPS) (Perkin Elmer XPS 5500, Mg source). The pyrene functionalized brushes show two clear peaks (Ag 3d) at the binding energy of around 370 eV, whereas as-grown brushes do not show observable Ag adsorption as shown in FIG. 3e. Calculation based on the peak (intensity) area of Ag relative to C (done by the RBD AugerScan Software upgrade) shows an Ag percentage of 0.1% (number of atoms). As shown in FIG. 3f, small Ag particles and aggregates were observed on the functionalized brush surface after H₂ reduction, confirming the adsorption of silver ions.

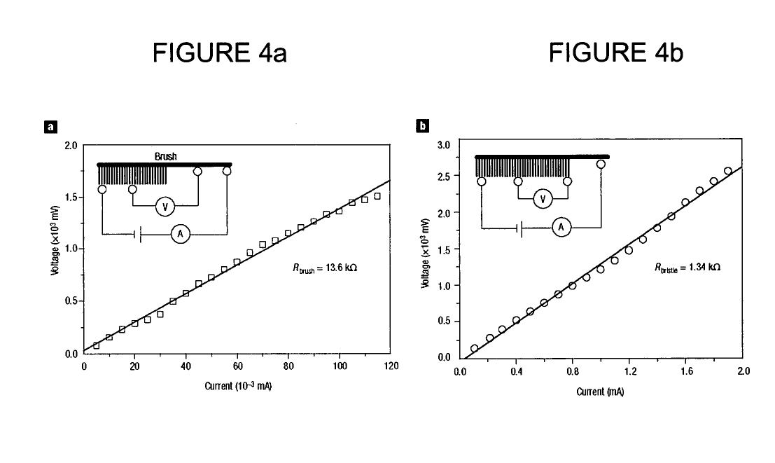

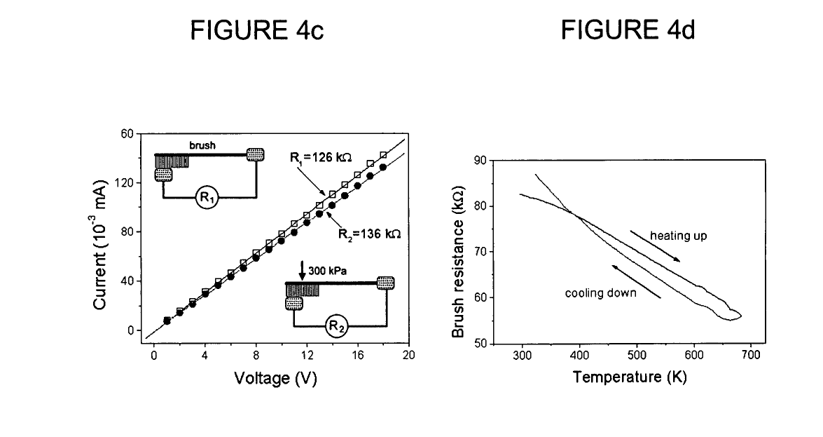

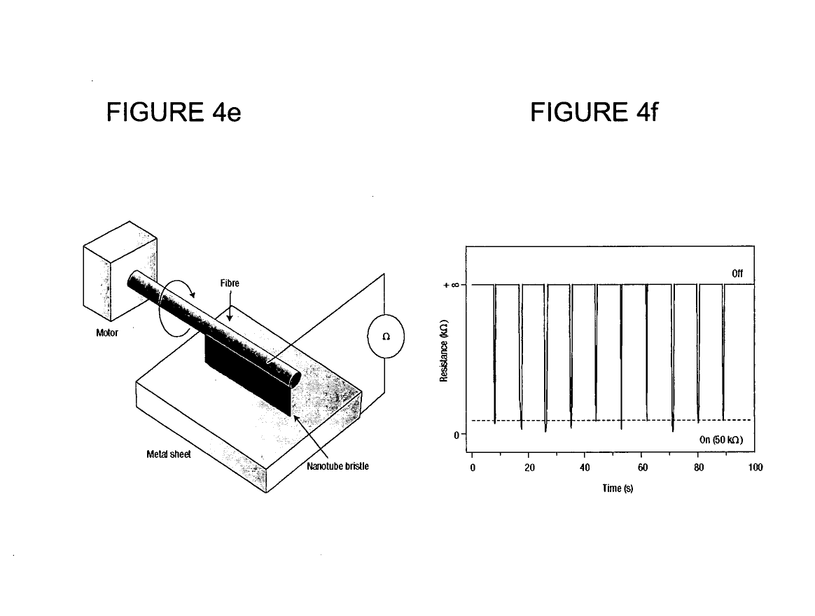

In another embodiment, since the nanotube bristles are electrically conductive, the brushes can act as flexible/movable contacts in relays or other electronic devices. Conductive brushes are commonly used in conjunction with slip rings or commutators to maintain an electrical connection in rotary and linear sliding contact applications. Conventional metal-to-metal contacts have suffered from local welding and formation of insulating interfacial films due to oxidation. The nanotube brushes provide a high level of contact redundancy, and could be miniaturized for coupling in MEMS devices. As shown in FIG. 4a, the total electrical resistance of a 2-mm-long brush (R_{brush}) consisting of 1-mm bristles and a 1-mm handle was measured to be ˜13.6 kΩ through a four-probe setup, which combines both the contribution from the nanotubes and gold-coated fiber. Four tungsten wires (50 μm in diameter) were fixed in parallel and spaced 2 mm from each other. The brush was placed on the top in contact with the underlying four wires, and its position was adjusted to leave the bristle handle or only the bristle part sitting in between the middle two wires (see insets in FIG. 4a,b). Electrical current was supplied through the outside two wires, and a voltage meter was connected to the two middle wires. As shown in FIG. 4b, the resistance from a 2-mm-span nanotube bristles prong (R_{bristle}) was 1.34 kΩ. Thus most of the brush resistance (90%) comes from the poorly conducting handle, which can be replaced by a more conducting handle, such as a metal handle. The resistivity (ρ) of pure nanotube bristles is ρ=R_{bristle}S/L=7.5×10⁻² Ωcm, where S is the cross-sectional area of a prong of bristle (S=1.12×10⁻³ mm² for a prong width and height of 16 and 70 μm, respectively) and L is the bristle span (2 mm). The nanotube resistivity (7.5×10⁻² Ωcm) is similar to previous reports on aligned nanotube films (6.6×10⁻² Ωcm).

The nanotube bristles are mechanically and electrically stable when being pressed (>300 kPa) or heated to 673 K, as shown in FIGS. 4c and 4d, respectively. FIG. 4c illustrates the pressure dependence of brush resistance. The upper line and upper inset illustrate a plot and measurement configuration, respectively, for a reference brush. The lower line and lower inset illustrate a plot and measurement configuration, respectively, for a brush whose bristles were pressed by a 50 mg metal bar with an estimated pressing stress of about 300 kPa. A slight increase in brush resistance was observed versus the reference brush, which is believed to have been caused by curling and separation of the pressed nanotubes. FIG. 4d illustrates the brush resistance recorded at an elevated temperature up to 673K. The brush was clamped on the handle and bristle end by two tungsten wires and placed into a small oven to heat to a set temperature. Four clamps were not used due to the difficulty in attaching four clamps to a single brush. The small observed decrease in resistance is believed to be due to a decreased contact resistance with increasing temperature due to a more intimate brush-tungsten contact. FIGS. 4c and 4d demonstrate that the brushes do not fail under high pressure or elevated temperature and still maintain a good conductivity under these conditions.

In addition to the role of an electrical contact, the nanotube brushes can act as electromechanical switches. FIG. 4e shows a single-prong brush on top of a flat metal pad (as contact electrode), with its fiber handle as a rotating spindle. This configuration can work as a current switch with controllable frequency, determined by the rotating speed of the brush. The ‘on’ and ‘off ’ state is defined when the nanotubes touch (on) or leave (off) the underlying metal pad during rotation. The oscillation in the resistance changes as the brush rotates is shown in FIG. 4f. An average resistance of ˜50 kΩ was seen periodically in every rotation occurring at a constant speed of 7 r.p.m. Much of this resistance is due to the interface between nanotubes and the metal. The switch-on resistance was maintained over several thousand cycles.

The nanotube brushes described here integrate several unique applications, including but not limited to cleaning of nanoparticles on planar/rough surfaces, painting inside capillary, adsorption of organic solvents and removal of metal ions, and as rotating electrical contacts. These durable, nanotube brushes could serve as versatile, anti-static, heat-tolerant tools in many industrial and environmental applications.

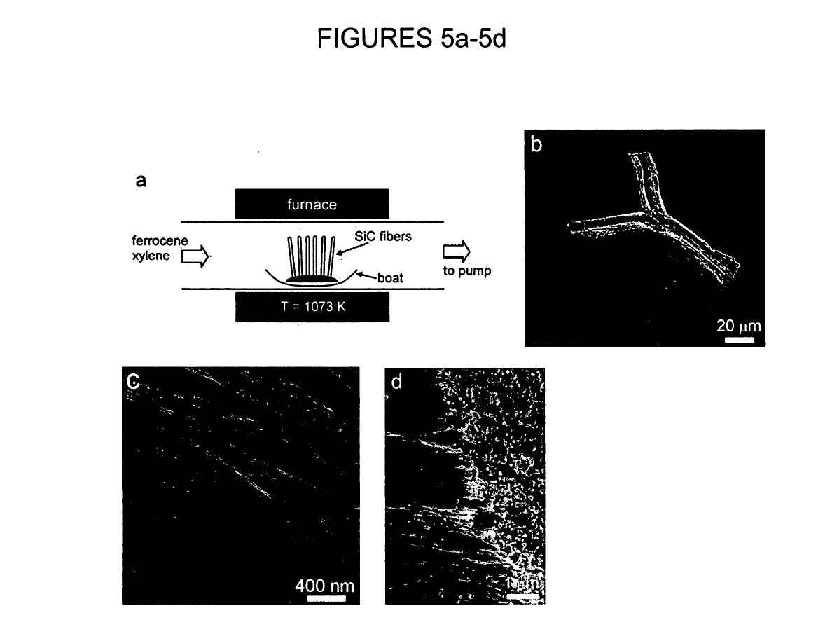

The exemplary nanotube CVD deposition process included the following steps. A solution made by dissolving 0.3 g ferrocene into 30 ml xylene was injected into the furnace through a rotating syringe pump at a constant speed (0.5 ml min⁻¹). Argon was flowed at 40 s.c.c.m. to carry the solution into a pre-heated steel bottle (180° C.) before entering the furnace. SiC fibers were put (either vertically or horizontally) in the middle of the furnace. The typical reaction temperature was 800° C., and the growth time took 10 minutes to one hour. FIG. 5a illustrates the furnace containing a boat. The SiC fibers are fixed vertically inside the boat by an industrial strength fireproof adhesive. The carbon source gas (xylene) and the catalyst gas (ferrocene) are flowed through the furnace and contact the SiC fibers to grow the nanotube bristles on unmasked portions of the fibers.

Vertical placement of fibers usually yields three nanotube prongs surrounding the fiber, as shown in FIG. 5b. FIGS. 5c and 5d, respectively, illustrate the aligned nanotubes in each prong and the closely arranged nanotube tips exposed from the prong edge. The formation of three-pronged morphology is due to the self-selected growth of dense nanotube arrays as they grow outwards from the cylindrical surface of the fiber, having circular cross-section, as the circumference surrounding the nanotube front surface is enlarged as the front moves away from the fiber nanotube interface. Two- and one-prong structures were obtained by lying the fibers down on a flat surface during CVD, to block the nanotube growth from the unwanted direction.

Shadow masking of gold on the SiC fibers were done in a 50-mtorr Ar plasma at an anode voltage of 12 V and a constant current of 30 mA with fiber ends (or other portions) covered by an aluminum foil. A 15-nm-thick Au layer was used for effective masking (inhibiting nanotube growth). The aluminum foil is removed before nanotube growth.

Thus, in the preferred method, the nanotubes are formed on the handle by a CVD method in which the carbon source gas and the catalyst source gas are used to grow the nanotubes on unmasked portions of the handle. The masking material may comprise any material, such as a metal, for example gold or copper, which prevents nanotube growth on the material when the carbon and catalyst source gases are provided onto the material. The handle material may comprise a ceramic, glass or semiconductor material, such as SiC, silicon oxide, silicon oxynitride, magnesium oxide, aluminum oxide or indium tin oxide.

In an alternative embodiment, the catalyst is not provided from the gas phase during nanotube growth. Instead, the nanotube growth catalyst is formed on at least one portion of the handle prior to nanotube growth. For example, a metal catalyst, such as Fe, Co, Pt, Ni, or their silicides, may be formed on one or more portions of the handle by evaporation, sputtering, CVD, dip coating, etc. The catalyst may be in nanoparticle or island form. Then, the catalyst coated handle is provided into a CVD chamber and nanotubes are selectively grown on the catalyst coated portion(s) of the handle. For example, the nanotubes can be selectively grown on the catalyst coated portion(s) of the handle by plasma enhanced CVD using acetylene carbon source gas or by thermal CVD using methane carbon source gas. The nanotubes do not grown on portion(s) of the handle that are not coated by the catalyst. A similar process may be used to grow nanowires and other nanostructures on the handle, by providing an appropriate source gas.

Although the foregoing refers to particular preferred embodiments, it will be understood that the present invention is not so limited. It will occur to those of ordinary skill in the art that various modifications may be made to the disclosed embodiments and that such modifications are intended to be within the scope of the present invention. All of the publications, patent applications and patents cited herein are incorporated herein by reference in their entirety.

1. A brush comprising:
a microscale handle; and
nanostructure bristles located on at least one portion of the handle.

2. The brush of claim 1, wherein the handle comprises a rod having a width or diameter of 100 microns or less.

3. The brush of claim 2, wherein the nanostructure bristles comprise carbon nanotubes.

4. The brush of claim 3, wherein the bristles extend in a plurality of directions from at least one end of the handle.

5. The brush of claim 4, wherein the bristles extend radially in 360 degrees from a cylindrical rod shaped handle.

6. The brush of claim 2, wherein the handle comprises a microfiber having a diameter of 50 microns or less.

7. The brush of claim 3, wherein the handle is connected to a motor which is adapted to move the handle in at least one of a sweeping or rotating motions.

8. The brush of claim 7, wherein the brush comprises an electrical contact or switch located in an electronic device.

9. A method of making a brush, comprising:
masking a first portion of a microscale handle; and
selectively growing nanostructure bristles on a second exposed portion of the handle.

10. The method of claim 9, wherein the handle comprises a rod having a width or diameter of 100 microns or less.

11. The method of claim 9, wherein the handle comprises a microfiber having a diameter of 50 microns or less.

12. The method of claim 9, wherein the nanostructure bristles comprise carbon nanotubes.

13. The method brush of claim 12, wherein the bristles extend in a plurality of directions from at least one end of the handle.

14. The method of claim 12, wherein the step of selectively growing comprises selectively growing the carbon nanotubes using CVD on the second portion of the handle.

15. A method of using a brush, comprising brushing an object using the brush of claim 1.

16. The method of claim 15, wherein the step of brushing the object comprises: brushing debris from a surface.

17. The method of claim 15, wherein the step of brushing the object comprises: brushing nanoparticles from a surface of a semiconductor device.

18. The method of claim 15, wherein the step of brushing the object comprises: mechanically moving the brush such that the bristles contact a solid surface or a liquid.

19. The method of claim 15, wherein the step of brushing the object comprises: coating a surface of the object with paint located on the bristles.

20. The method of claim 15, wherein the step of brushing the object comprises: stirring a liquid by moving the brush in the liquid.

21. The method of claim 15, wherein the step of brushing the object comprises: providing the brush into a fluid to selectively absorb at least one component of the fluid onto the bristles.

22. The method of claim 21, wherein the bristles are functionalized to selectively absorb the at least one component of the fluid.

23. The method of claim 15, wherein the step of brushing the object comprises: moving the bristles to contact a conductive surface to form an electrical contact between the conductive surface and the handle.

24. The method of claim 23, wherein the brush acts as an electro mechanical current switch.
